(19) United States
(12) Patent Application Publication
(10) Pub. No.: US 2019/0250317 A1
(43) Pub. Date: Aug. 15, 2019

(54) POLARIZING UNIT, METHOD OF MANUFACTURING THE SAME, AND DISPLAY DEVICE INCLUDING THE POLARIZING UNIT

(71) Applicant: Samsung Display Co., Ltd., Yongin-si (KR)

(72) Inventors: Jinwoo CHOI, Seoul (KR); Jaeik LIM, Hwaseong-si (KR); Minwoo KIM, Hwaseong-si (KR); Wonsang PARK, Yongin-si (KR); Euna YANG, Yongin-si (KR); Haeyun CHOI, Hwaseong-si (KR)

(21) Appl. No.: 16/275,201

(22) Filed: Feb. 13, 2019

(30) Foreign Application Priority Data
Feb. 14, 2018 (KR) 10-2018-0018184

(51) Int. Cl. G02B 5/30; H01L 51/52; H01L 51/00; G06F 3/041

(52) U.S. Cl. CPC G02B 5/3016; H01L 51/5281; H01L 27/3244; G06F 3/041; H01L 51/0097

(57) ABSTRACT

Disclosed herein are a polarizing unit, a method of manufacturing the same, and a display device including the polarizing unit. The polarizing unit includes: an upper substrate; a coating polarizer disposed on one surface of the upper substrate; a coating retarder disposed on one surface of the coating polarizer; and pressure-sensitive adhesive layers respectively disposed between the upper substrate and the coating polarizer and between the coating polarizer and the coating retarder; the upper substrate including a flexible material having elasticity.

### CROSS-REFERENCE TO RELATED APPLICATION

This application claims priority to and the benefit of Korean Patent Application No. 10-2018-0018184, filed on Feb. 14, 2018, in the Korean Intellectual Property Office (KIPO), the entire content of which is incorporated herein by reference.

### BACKGROUND

### 1. Field

The present disclosure relates generally to a polarizing unit, a method of manufacturing the polarizing unit, and a display device including the polarizing unit.

### 2. Discussion of Related Art

With the development of the information-oriented society, demand for various types (or kinds) of image display devices is increasing. Recently, there have been used various flat panel display devices, such as liquid crystal display devices, plasma display devices, organic light-emitting diode display devices, and electrophoretic display devices.

In recent years, as mobile devices, such as mobile phones, portable multimedia players (PMPs), personal digital assistants (PDAs), and notebooks, have been developed, display devices are increasingly used in outdoor environments that are rich in external light, such as solar light. In this case, external light may be reflected or scattered on the display surface of such a mobile device, and thus contrast and visibility implemented on the display device of the mobile device may be degraded. Furthermore, when the display device is used indoors, visibility may be degraded due to various types (or kinds) of external light, such as the light of a fluorescent lamp.

In some display devices, in order to prevent (or reduce) the degradation of visibility attributable to external light, a film-type (or film-kind) of circular polarizing film is attached onto the overall surface (or display surface) of a display device. However, the circular polarizing film is manufactured by attaching films in a plurality of layers, and thus a manufacturing process is complicated and a thickness becomes large, with the result that there has been difficulty implementing a thin display device.

Furthermore, recently, attention has been attracted by flexible display devices, such as curved displays in each of which a flat panel display device is formed in a curved shape, foldable displays in each of which a flat panel display device is foldable, stretchable displays in each of which a flat panel display device is bendable or stretchable, etc. A polarizing plate provided in such a flexible display also needs to have flexibility.

It is to be understood that this background of the technology section is intended to provide useful background for understanding the technology and as such disclosed herein, the technology background section may include ideas, concepts or recognitions that were not part of what was known or appreciated by those skilled in the pertinent art prior to a corresponding effective filing date of subject matter disclosed herein.

### SUMMARY

An exemplary embodiment of the present disclosure may be directed to a polarizing unit which has a small thickness, flexibility, and excellent optical reliability.

According to an aspect of an embodiment of the present disclosure, there is provided a polarizing unit including: an upper substrate; a coating polarizer disposed on one surface of the upper substrate; a coating retarder disposed on one surface of the coating polarizer; and pressure-sensitive adhesive layers respectively disposed between the upper substrate and the coating polarizer and between the coating polarizer and the coating retarder; wherein the upper substrate includes a flexible material having elasticity.

The flexible material having elasticity of the upper substrate may include a material having an elastic modulus of about 1 GPa or less.

The upper substrate may include one or more selected from an olefin elastomer, a urethane elastomer, and a polyester elastomer.

The upper substrate may include one or more selected from polyethyleneterephthalate (PET), polyethylenenaphthalate (PEN), polydimethylsiloxane (PDMS), polyimide (PI), polyimideamide, polyetherimide (PEI), polyacrylate (PAC), and polymethylmethacrylate (PMMA).

The coating retarder may delay the phase of transmitted light by about λ/4, and the optical axis directions of the coating retarder and the coating polarizer may form an angle of about 45 degrees.

The coating polarizer and the coating retarder may each include a liquid crystal compound.

The pressure-sensitive adhesive layer may include one or more selected from a natural rubber adhesive, a styrene/butadiene latex adhesive, ABA block copolymer thermoplastic rubber (wherein A is a thermoplastic polystyrene end block and B is an intermediate block of polyisoprene rubber, polybutadiene rubber, polyethylene rubber, or polybutylene rubber), butyl rubber, polyisobutylene, an acrylic polymer adhesive, and a vinyl ether polymer adhesive.

According to another aspect of an embodiment of the present disclosure, there is provided a method of manufacturing a polarizing unit, the method including: forming a coating polarizer on one surface of a base substrate; forming a pressure-sensitive adhesive layer on one surface of the coating polarizer; forming a coating retarder on one surface of a transfer substrate; attaching the coating retarder onto the pressure-sensitive adhesive layer, and removing the transfer substrate; removing the base substrate from the coating polarizer; and forming a pressure-sensitive adhesive layer on the back of the coating polarizer free from the base substrate, and attaching an upper substrate onto the latter pressure-sensitive adhesive layer.

Forming the coating polarizer on the one surface of the base substrate may include: forming an alignment layer on the top surface of the base substrate; and forming a liquid crystal coating layer on the alignment layer by applying a coating layer formation composition, including a liquid crystal compound and a dichroic dye, onto the alignment layer.

Forming the coating retarder on the one surface of the transfer substrate may include: forming an alignment layer on the transfer substrate; and forming a liquid crystal coating layer on the alignment layer by applying a coating layer formation composition, including a liquid crystal compound, onto the alignment layer.

According to still another aspect of an embodiment of the present disclosure, there is provided a display device including: a display panel configured to display images; and a polarizing unit disposed on the top of the display panel; wherein the polarizing unit includes: an upper substrate; a coating polarizer disposed on one surface of the upper substrate; a coating retarder disposed on one surface of the coating polarizer; and pressure-sensitive adhesive layers respectively disposed between the upper substrate and the coating polarizer and between the coating polarizer and the coating retarder; wherein the upper substrate includes a flexible material having elasticity.

The display device may further include a touch sensing unit disposed on the display panel.

The display device may further include an adhesive layer disposed between the polarizing unit and the touch sensing unit.

The display panel may include: a substrate; a drive circuit unit disposed on the substrate; light emitting diodes coupled (or connected) to the drive circuit unit; and a sealing layer configured to cover the light emitting diodes.

The upper substrate may be a window.

The display panel may be a stretchable display panel.

### BRIEF DESCRIPTION OF THE DRAWINGS

A more complete appreciation of the subject matter of the present disclosure will become more apparent by describing in more detail exemplary embodiments thereof with reference to the accompanying drawings, wherein:

FIG. 1 is a schematic sectional view of a polarizing unit according to the first exemplary embodiment of the present disclosure;

FIG. 2 is a sectional view schematically showing a method of manufacturing the polarizing unit of FIG. 1;

FIG. 3 is an image showing the results of the elongation of another polarizing unit;

FIG. 4 is an image, and an expanded view of the image, showing the result of the elongation of the polarizing unit according to the first exemplary embodiment of the present disclosure;

FIG. 5 is a graph showing phase delay values at a reference wavelength of 550 nm based on the elongation of the polarizing unit according to the first exemplary embodiment of the present disclosure;

FIG. 6 is a graph showing phase delay values for wavelengths based on the elongation of the polarizing unit according to the first exemplary embodiment of the present disclosure;

FIG. 7 is a graph showing color differences based on the elongation of the polarizing unit according to the first exemplary embodiment of the present disclosure;

FIG. 8 is a graph showing reflectances based on the elongation of the polarizing unit according to the first exemplary embodiment of the present disclosure;

FIG. 9 is a plan view of an organic light-emitting display device according to a second exemplary embodiment of the present disclosure;

FIG. 10 is a sectional view taken along line I-I′ of FIG. 9;

FIG. 11 shows the optical axis directions of a coating retarder and a coating polarizer included in the polarizing unit according to the first exemplary embodiment of the present disclosure;

FIG. 12 schematically shows the reflection prevention (or reduction) principle of the polarizing unit according to the first exemplary embodiment of the present disclosure; and

FIGS. 13-14 are sectional views of an organic light-emitting display device according to a third exemplary embodiment of the present disclosure.

### DETAILED DESCRIPTION

Features of the present disclosure and methods for achieving them will be made clear from exemplary embodiments which will described below in more detail in conjunction with reference to the accompanying drawings. The present disclosure may, however, be embodied in many different forms and should not be construed as being limited to the exemplary embodiments set forth herein. Rather, these exemplary embodiments are provided so that this disclosure will be thorough and complete, and will fully convey the scope of the present disclosure to those skilled in the art. The present disclosure is merely defined by the scope of the claims, and equivalents thereof. Therefore, well-known constituent elements, operations and techniques are not described in more detail in the exemplary embodiments in order to prevent the present disclosure from being obscurely interpreted. Throughout the specification, like reference numerals refer to like elements.

Unless otherwise defined, all terms used herein (including technical and scientific terms) have the same meaning as commonly understood by those skilled in the art to which this present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

The present disclosure will be described in more detail below with reference to the accompanying drawings.

The present disclosure provides a polarizing unit including: an upper substrate; a coating polarizer disposed on one surface of the upper substrate; a coating retarder disposed on one surface of the coating polarizer; and pressure-sensitive adhesive layers respectively disposed between the upper substrate and the coating polarizer and between the coating polarizer and the coating retarder; wherein the upper substrate includes a flexible material having elasticity.

The polarizing unit according to the present disclosure is a layered unit including a composite configuration of the coating polarizer and the coating retarder which have ultraviolet blocking property. The polarizing unit may be used to implement a thin, lightweight display device, is excellent in terms of flexibility and optical reliability because it includes the upper substrate having elasticity, and may be applied to devices having various suitable shapes.

Furthermore, the present disclosure provides a method of manufacturing a polarizing unit, the method including: forming a coating polarizer on one surface of a base substrate; forming a pressure-sensitive adhesive layer on one surface of the coating polarizer; forming a coating retarder on one surface of a transfer substrate; attaching the coating retarder onto the pressure-sensitive adhesive layer, and removing the transfer substrate; removing the base substrate from the coating polarizer; and forming a pressure-sensitive adhesive layer on the back of the coating polarizer free from the base substrate, and attaching an upper substrate onto the latter pressure-sensitive adhesive layer.

The method of manufacturing a polarizing unit according to the present disclosure is a method including forming the layers having a polarization function on the base substrate resistant to heat and transferring the layers onto the upper substrate having elasticity. In accordance with the method of manufacturing a polarizing unit according to the present disclosure, there can be manufactured the polarizing unit which is excellent in terms of optical reliability and flexibility.

Furthermore, the present disclosure provides a display device including: a display panel configured to display images; and the polarizing unit according to the present disclosure disposed on the top of the display panel.

The display device according to the present disclosure can secure excellent flexibility, can be formed to be lightweight and thin, and can improve image visibility.

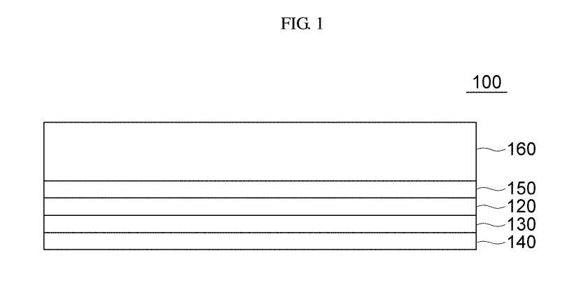

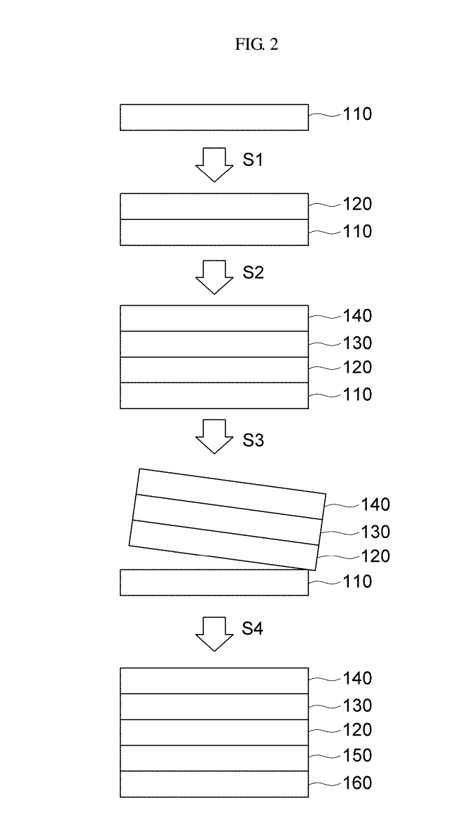

Referring to FIGS. 1-2 together, there are described a polarizing unit 100 and a method of manufacturing the same according to a first exemplary embodiment of the present disclosure.

The polarizing unit 100 according to the first exemplary embodiment of the present disclosure includes a coating retarder 140, a pressure-sensitive adhesive layer 130, a coating polarizer 120, a pressure-sensitive adhesive layer 150, and an upper substrate 160.

In the first exemplary embodiment of the present disclosure, the coating polarizer 120 is an optical film configured to convert incident external light into a desired single polarization state (a linear polarization state). The coating polarizer 120 functions as a polarizer, and may be formed on at least one surface of the base substrate 110.

For example, the coating polarizer 120 may be formed by forming an alignment layer through the application of an alignment layer formation composition on the base substrate 110 and the impartment of orientation and then forming a liquid crystal coating layer through the application of a coating layer formation composition, including a liquid crystal compound and a dichroic dye, onto the alignment layer (see S1 of FIG. 2).

The coating polarizer 120 may be formed to have a thinner thickness than a common polarizing plate (e.g., a polarizing plate including a polyvinyl alcohol-based polarizer and protective films attached onto both surfaces of the polarizer via an adhesive).

A film which is excellent in terms of transparency, mechanical strength, thermal stability, a moisture blocking property, and isotropy may be used as the base substrate 110. An example of the film may be a film including polyester resin, cellulose resin, polycarbonate resin, styrene resin, polyolefin resin, and/or vinyl chloride resin.

The alignment layer formation composition is a solution in which a polymer and a coupling agent are dissolved in an organic solvent. The alignment layer formation composition is applied onto the base substrate 110 by spin coating, gravure coating, or the like. After the application, orientation may be imparted to the alignment layer in a direction in which polarized light is polarized by radiating polarized light onto the alignment layer formation composition.

The polymer contained in the alignment layer formation composition may be a polymer, such as polymethyl methacrylate, an acrylic acid-methacrylic acid copolymer, a styrene-maleimide copolymer, polyvinyl alcohol, modified polyvinyl alcohol, gelatin, a styrene-vinyl toluene copolymer, chlorosulfonated polyethylene, nitrocellulose, polyvinyl chloride, polyolefin chloride, polyester, polyimide, a vinyl acetate-vinyl chloride copolymer, an ethylene-vinyl acetate copolymer, carboxymethyl cellulose, polyethylene, polypropylene, polycarbonate, and/or the like. Furthermore, the coupling agent may be a silane coupling agent, and/or the like.

The coating layer formation composition may include a liquid crystal compound having optical anisotropy and an optically or thermally crosslinkable property and a dichroic dye.

The liquid crystal compound may include, for example, a reactive liquid crystal compound (reactive mesogen (RM)). The reactive liquid crystal compound refers to a monomer molecule which includes mesogen capable of exhibiting liquid crystallinity and an end group capable of polymerizing and has a liquid crystal phase. The end group capable of polymerizing may be an acrylic group, a methacryl group, or the like. As an example, the reactive liquid crystal compound may include a monoacrylate-type (or a monoacrylate-kind) of reactive liquid crystal compound and a diacrylate-type (or a diacrylate-kind) of reactive liquid crystal compound. When the reactive liquid crystal compound is polymerized, there is obtained a polymer network which is crosslinked while maintaining the aligned phase of liquid crystals.

A liquid crystal-phase crosslinked network film formed as described above has a solid thin film shape while maintaining the characteristics of liquid crystals, such as optical anisotropy, a dielectric constant, etc., and is thus mechanically or thermally stable.

The dichroic dye refers to a dye which, for a set or determined wavelength range, absorbs one of the two polarized orthogonal components and transmits the other. In other words, the dichroic dye has the characteristic of linearly polarizing light. The dichroic dye may include an anthraquinone dye, a phthalocyanine dye, a porphyrin azo dye, a non-azo dye, and/or a triazo dye. In particular, a dichroic azo dye is suitable or appropriate.

When a reactive liquid crystal compound is polymerized, the dichroic dye is dispersed among liquid crystals and oriented in the same (e.g., substantially the same) direction as the liquid crystals.

Although a method of applying the coating layer formation composition is not limited to a particular method, die coating, pin coating, roll coating, dispensing coating, gravure coating, etc. may be used. The type (or kind) and amount of solvent to be used may be determined according to the coating method.

The solvent contained in the coating layer formation composition is evaporated via a drying process. After the drying, a liquid crystal coating layer is formed by optically setting the coating layer formation composition through light radiation using an ultraviolet ray or like or by thermally setting the coating layer formation composition through heat radiation using a heater or the like.

The thickness of the coating polarizer 120 may be in a range of about 0.5 μm to about 10 μm, for example, about 0.5 μm to about 5 μm.

In the first exemplary embodiment of the present disclosure, the pressure-sensitive adhesive layers 130 and 150 are respectively interposed between the coating polarizer 120 and the coating retarder 140 and between the coating polarizer 120 and the upper substrate 160, and function to attach the coating polarizer 120 and the coating retarder 140 or the coating polarizer 120 and the upper substrate 160 to each other.

The pressure-sensitive adhesive layers 130 and 150 may include a pressure sensitive adhesive. Furthermore, the pressure-sensitive adhesive layers 130 and 150 may further include at least one additive selected from the group consisting of a plasticizer, a tackifier, a filler, and a cross-linking agent.

When pressure is applied to the pressure-sensitive adhesive layers 130 and 150, adhesive force for the coating polarizer 120 and the coating retarder 140 and adhesive force for the coating polarizer 120 and the upper substrate 160 may be increased.

The pressure sensitive adhesive contained in the pressure-sensitive adhesive layers 130 and 150 may include: a natural rubber adhesive; a styrene/butadiene latex adhesive; an acrylic polymer adhesive, such as ABA block copolymer thermoplastic rubber (wherein A is a thermoplastic polystyrene end block and B is the intermediate block of polyisoprene rubber, polybutadiene rubber, polyethylene rubber, or polybutylene rubber), butyl rubber, polyisobutylene, polyacrylate, and a vinyl acetate/acrylic ester copolymer; a vinyl ether polymer adhesive, such as polyvinyl methyl ether, polyvinyl ethyl ether, and/or polyvinyl isobutyl ether; etc.

The thickness of the pressure-sensitive adhesive layers 130 and 150 may be (or may each be) in a range of about 0.5 μm to about 10 μm, for example, about 5 μm to about 10 μm.

In the first exemplary embodiment of the present disclosure, the coating retarder 140 functions to delay the phase of transmitted light by about λ/4. In other words, the phase difference of the coating retarder 140 is λ/4. The coating retarder 140 may include a reactive liquid crystal compound.

A method of forming the coating retarder 140 by using a reactive liquid crystal compound is as follows:

First, an alignment layer is formed by applying an alignment layer formation composition onto a transfer substrate and imparting orientation, and a liquid crystal coating layer is formed by applying a coating layer formation composition, including a liquid crystal compound, onto the alignment layer. Thereafter, the coating retarder 140 is formed by attaching the liquid crystal coating layer onto the pressure-sensitive adhesive layer 130 and then removing the transfer substrate.

As described above, the coating retarder 140 may be formed on the pressure-sensitive adhesive layer 130 disposed on the coating polarizer 120, and then the coating polarizer 120 and the coating retarder 140 may be attached via the pressure-sensitive adhesive layer 130 by applying pressure (see S2 of FIG. 2).

The transfer substrate is a base substrate for the above-described coating polarizer 120, and the exemplary polymer film may be used as the transfer substrate.

Since the alignment layer formation composition and methods of drying and applying the same are the same (e.g., substantially the same) as those described in connection with the coating polarizer, redundant descriptions thereof are not repeated here.

The composition of the coating layer formation composition is the same (e.g., substantially the same) as those described in connection with the coating polarizer except that a dichroic dye is excluded. Furthermore, since methods of applying, drying and curing the coating layer formation composition are the same (e.g., substantially the same) as those described in connection with the coating polarizer, redundant descriptions thereof are not repeated here.

In order to delay light, passing through the coating retarder 140, by λ/4, the thickness of the coating retarder 140 may be in a range of about 0.5 μm to about 10 μm, for example, about 0.5 μm to about 5 μm.

As described above, after the coating polarizer 120 and the coating retarder 140 have been attached to each other, the base substrate 110 is removed (see S3 of FIG. 2).

By removing the base substrate 110, there may be obtained a layered object in which the coating retarder 140, the pressure-sensitive adhesive layer 130, and the coating polarizer 120 are sequentially disposed. The layered object may be transferred or attached onto any suitable location of an object requiring a polarization function.

In the first exemplary embodiment of the present disclosure, the pressure-sensitive adhesive layer 150 is formed on the back of the coating polarizer 120 free from the base substrate 110, and then the upper substrate 160 is attached to the pressure-sensitive adhesive layer 150 (see S4 of FIG. 2).

In the first exemplary embodiment of the present disclosure, the upper substrate 160 is located in the highest portion of the polarizing unit 100, and may function to protect the coating polarizer 120 and the coating retarder 140. Generally, in the case of polarizing plates currently used, a display device is protected using a method of locating a protective film, such as a TAC film, in order to improve surface hardness, wear resistance, and scratch resistance and forming a hard coating layer on the top surface of the protective film. Alternatively or additionally, there may be used a method of adding a cover plate made of glass to the top of a protective film, such as a TAC film, or to the top of a protective film on which a hard coating layer is formed. However, this method is also problematic in that a process is complicated, weight is increased, and there is the risk of damage. In contrast, the upper substrate 160 according to the present disclosure is formed unitarily with the coating polarizer 120, and thus has high surface hardness, high wear resistance, and high scratch resistance in itself. Accordingly, the upper substrate 160 does not require the formation of a separate hard coating layer or the application of a separate cover plate.

The upper substrate 160 may include a material having optical transparency and flexibility. For example, the upper substrate 160 may include elastomer (EL), e.g., a polymer compound having the property of extending when external force is applied and returning to its original size when the external force is removed, or polyurethane (PU), e.g., a polymer compound bonded via a urethane bond. Since the upper substrate 160 includes elastomer or polyurethane, the polarizing unit 100 may have excellent folding and flexible functions.

Meanwhile, when the polarizing unit 100 according to the first exemplary embodiment of the present disclosure is provided in a display device, the upper substrate 160 may be located in the highest portion of the display device, and may function as a window.

The upper substrate 160 may include a flexible material having elasticity. For example, the flexible material having elasticity of the upper substrate 160 may include a material having an elastic modulus of 1 GPa or less (e.g., the elasticity of the flexible material having elasticity may be 1 GPa or less). As an example, the upper substrate 160 may include one or more selected from olefin elastomer, urethane elastomer, and polyester elastomer. In this case, the upper substrate 160 may include a flexible material, and may thus have extensibility.

As another example, the upper substrate 160 may include one or more selected from polyethyleneterephthalate (PET), polyethylenenaphthalate (PEN), polydimethylsiloxane (PDMS), polyimide (PI), polyimideamide, polyetherimide (PEI), polyacrylate (PAC), and polymethylmethacrylate (PMMA).

As described above, the polarizing unit 100 according to the first exemplary embodiment of the present disclosure, in which the upper substrate 160 is formed unitarily with the coating polarizer 120, exhibits flexibility, bendability, and extensibility, and protects a film from damage attributable to repetitive, continuous bending or long-term folding. Accordingly, the polarizing unit 100 may be usefully applied to various suitable display devices, thereby implementing thin and lightweight devices.

For example, the polarizing unit 100 according to the first exemplary embodiment of the present disclosure has extensibility, and may be thus applied to stretchable display devices which are bendable or stretchable.

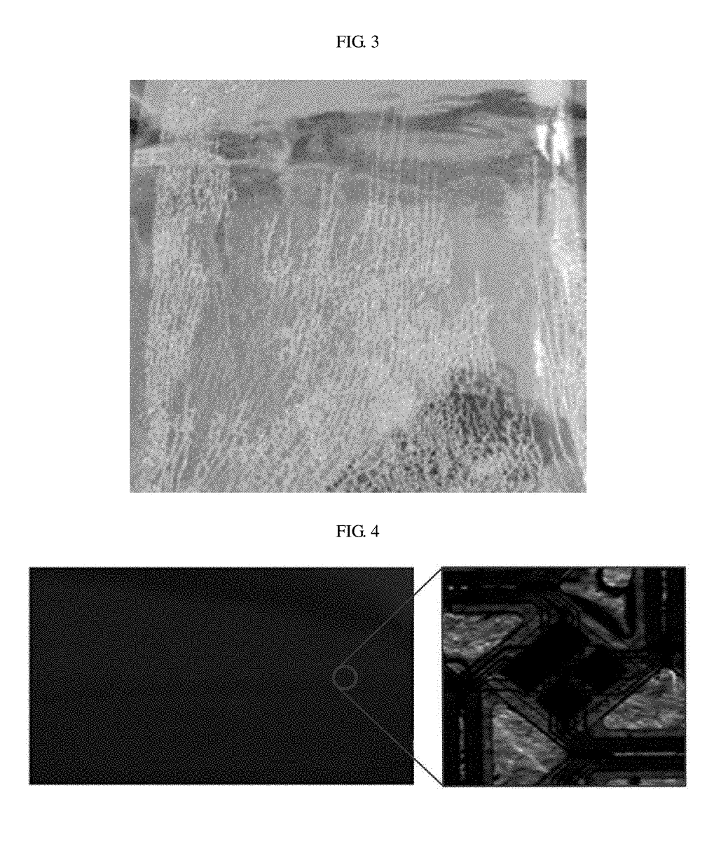

FIGS. 3-4 show the results of the elongation of another polarizing film and the results of the elongation of the polarizing unit according to the first exemplary embodiment of the present disclosure.

In this case, the polarizing film may be any suitable polarizing film, and examples thereof include a polyvinyl alcohol (PVA) film, and includes triacetyl cellulose (TAC) disposed on the polyvinyl alcohol (PVA) film as a protective layer. Triacetyl cellulose (TAC) disposed as a protective layer has high hardness, so that it is difficult to elongate the polarizing film, and triacetyl cellulose (TAC) causes a crack during an elongation process (see FIG. 3).

In contrast, it can be seen that damage, such as a crack, does not occur (or substantially does not occur) in the polarizing unit according to the first exemplary embodiment of the present disclosure even it is elongated by about 5% to about 15% (see FIG. 4).

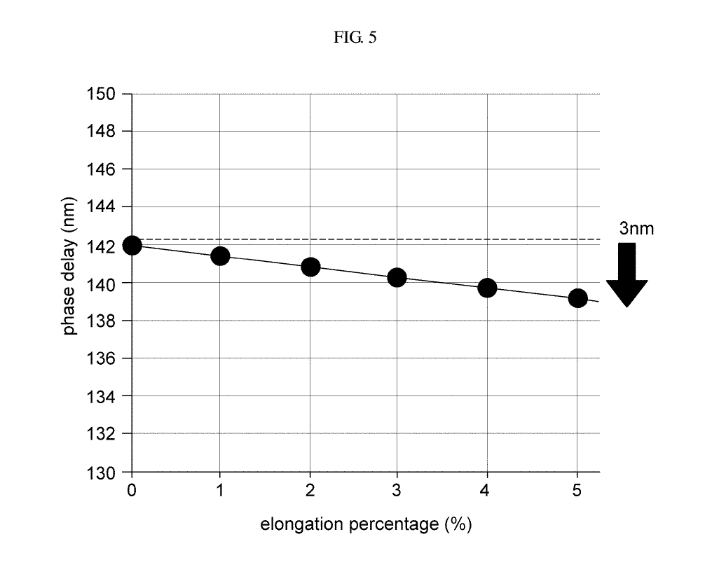

FIGS. 5-8 are graphs showing the results of the evaluation of optical reliability based on the elongation rigidity of the polarizing unit according to the first exemplary embodiment of the present disclosure.

The polarizing unit according to the first exemplary embodiment of the present disclosure has a structure in which the coating polarizer and the coating retarder are disposed on the upper substrate and the pressure-sensitive adhesive layers are respectively interposed therebetween.

According to the above-described layered structure, it may seem that the coating polarizer and the coating retarder are sequentially formed on the upper substrate. However, as described above, the polarizing unit according to the first exemplary embodiment of the present disclosure is manufactured by forming the coating polarizer and the coating retarder on the base substrate resistant to heat, removing the base substrate, and attaching the upper substrate having extensibility instead. The reason for this is that when the coating polarizer and the coating retarder are directly formed on the upper substrate, there is concern that a crack or a reduction in an optical characteristic may occur.

In other words, in the polarizing unit according to the first exemplary embodiment of the present disclosure, the coating polarizer and the coating retarder are formed on the base substrate resistant to heat, thereby preventing optical characteristics from being degraded (or reducing a likelihood or amount of such degradation). Furthermore, the upper substrate having extensibility is attached in place of a base substrate, thereby providing the characteristic of enabling elongation without damage, such as a crack.

FIG. 5 shows the phase delay values of light, transmitted through the polarizing unit according to the first exemplary embodiment of the present disclosure, for example, the coating retarder, which were measured at a wavelength of about 550 nm, e.g., about the intermediate wavelength of the visible spectrum. It can be seen that there is no significant difference between the phase delay value (142 nm) of the polarizing unit before elongation and the phase delay value (139 nm) of the polarizing unit after 5% elongation.

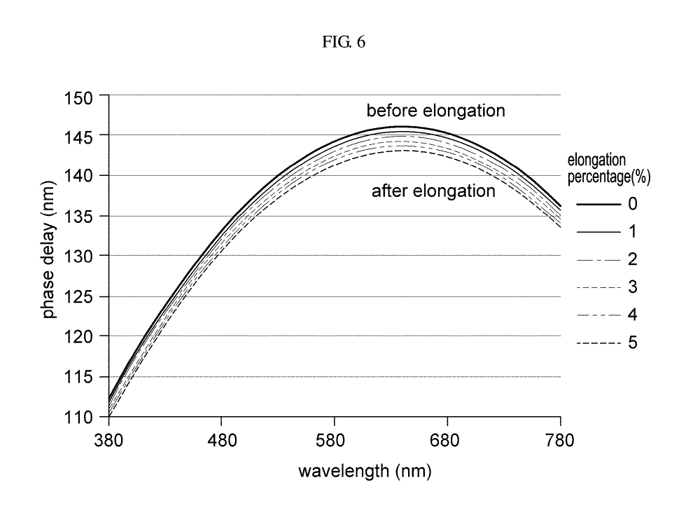

FIG. 6 shows the phase delay values of light, transmitted through the polarizing unit according to the first exemplary embodiment of the present disclosure, for example, the coating retarder, which were measured in a wavelength range of about 380 nm to about 780 nm, based on the intensities of elongation. It can be seen that there is no significant difference between the phase delay value of the polarizing unit before elongation and the phase delay values based on changes (1 to 5) in the intensity of elongation.

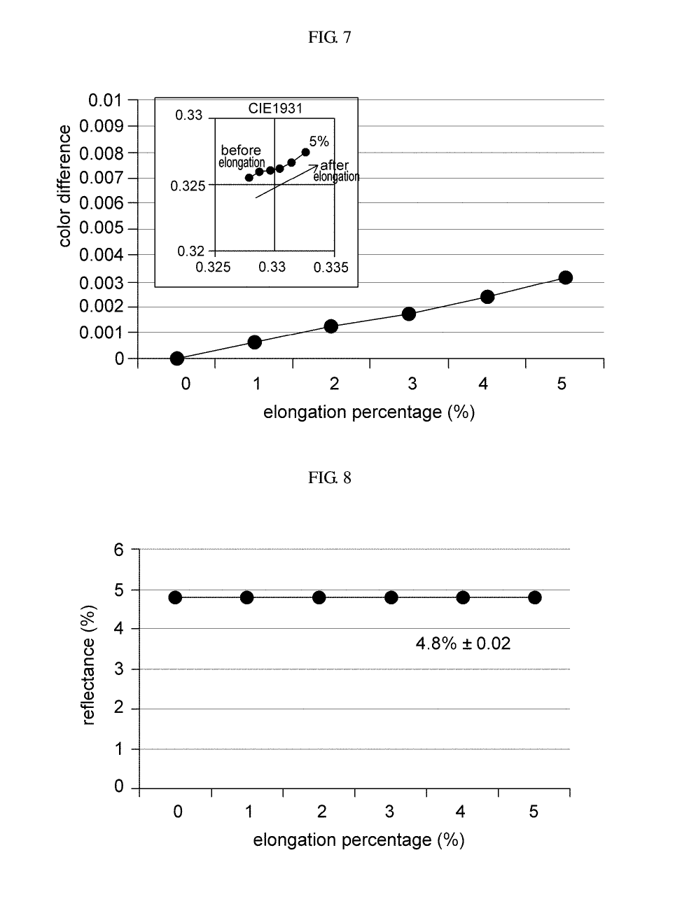

FIG. 7 shows the color differences of light, incident on the polarizing unit according to the first exemplary embodiment of the present disclosure, based on the intensities of elongation. It can be seen that there is no significant difference (about 0.003) between the color difference value of the polarizing unit before elongation and the color difference value of the polarizing unit after 5% elongation.

FIG. 8 shows the reflectances (%) of light which was incident on the polarizing unit according to the first exemplary embodiment of the present disclosure, was transmitted through the polarizing unit and was then exited to the outside. It can be seen that there is no significant difference between the reflectance of the polarizing unit before elongation and the reflectance of the polarizing unit after elongation.

The above-described polarizing unit according to the first exemplary embodiment of the present disclosure has extensibility in a range of about 5% to about 15%, and does not experience an excessive change in optical characteristics attributable to elongation, thereby providing optical reliability. Accordingly, the polarizing unit according to the first exemplary embodiment of the present disclosure may be applied to stretchable display devices which are bendable or stretchable.

Furthermore, the polarizing unit according to the first exemplary embodiment of the present disclosure may be used in various suitable fields. For example, the polarizing unit according to the first exemplary embodiment of the present disclosure may be installed and used in the curved, bendable, flexible, rollable, foldable, and stretchable touch panels of mobile communication terminals, smartphones, and tablet PCs, and various suitable types (or kinds) of displays as well as flat touch panels and displays.

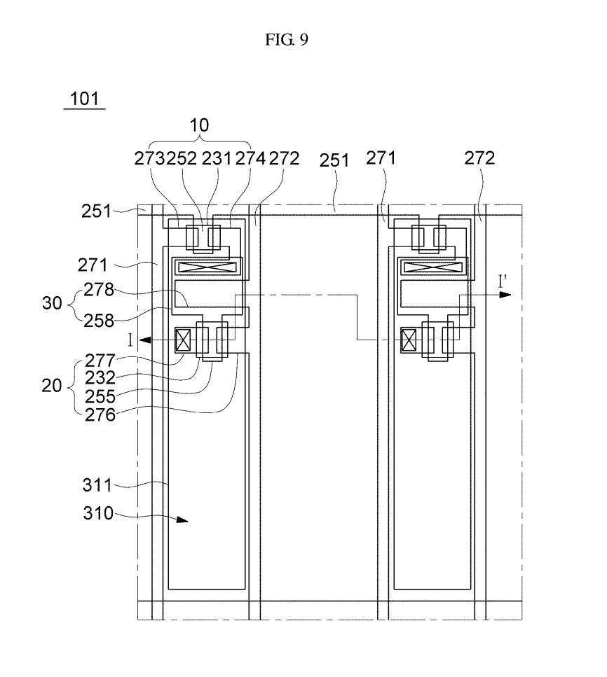

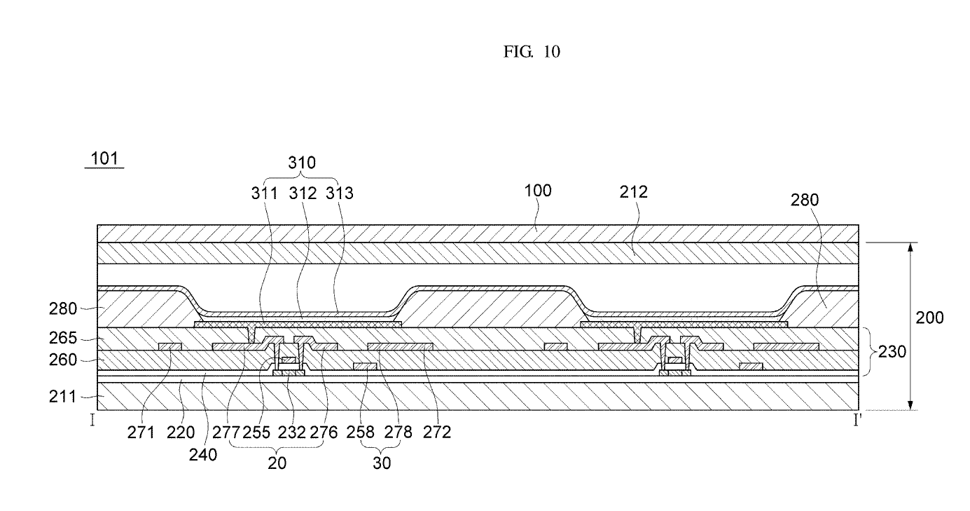

An organic light-emitting display device according to a second exemplary embodiment of the present disclosure will be described with reference to FIGS. 9-10.

FIG. 9 is a plan view of an organic light-emitting display device according to the second exemplary embodiment of the present disclosure, and FIG. 10 is a sectional view taken along line I-I′ of FIG. 9.

For example, the organic light-emitting display device 101 according to the second exemplary embodiment of the present disclosure includes a display panel 200, and a polarizing unit 100 disposed on the display panel 200.

The display panel 200 includes a substrate 211, a drive circuit unit 230, and organic light-emitting diodes 310.

The substrate 211 may include an insulating material selected from the group consisting of glass, quartz, ceramic, and plastic. Furthermore, a polymer film may be used as the substrate 211.

In this case, when the substrate 211 includes a plastic material having flexibility, the organic light-emitting display device 101 may become a flexible display device.

Meanwhile, the substrate 211 may be implemented as a stretchable substrate, in which case the organic light-emitting display device 101 may become a stretchable display device. In this case, the substrate 211 may include plastic or fabric which is bendable or stretchable. However, the material of the substrate 211 is not limited to plastic or fabric, and may include another material which is bendable or stretchable. Furthermore, the substrate 211 may include a reflecting plate. The reflecting plate may be formed on the substrate 211, needs to be bendable or stretchable, and may be implemented as a flexible foil.

A buffer layer 220 may be further disposed on the substrate 211. The buffer layer 220 may include one or more films selected from among various suitable inorganic and organic films. The buffer layer 220 may be omitted.

The drive circuit unit 230 is disposed on the substrate 211 (or buffer layer 220). The drive circuit unit 230 is a part including pluralities of thin film transistors 10 and 20 and capacitors 30, and drives the organic light-emitting diode 310. In other words, the organic light-emitting diode 310 emits light and displays images in response to drive signals received from the drive circuit unit 230.

In FIGS. 9-10, there is shown a 2 Tr-1 Cap-type (or Cap-kind) active matrix (AM) organic light-emitting display device 101 in which each pixel is provided with two thin film transistors (TFTs) 10 and 20 and a single capacitor 30. However, the second exemplary embodiment of the present disclosure is not limited to the structure. In this case, the term “pixel” refers to the smallest element of image representation, and the organic light-emitting display device 101 displays an image via a plurality of pixels.

Each pixel includes a switching thin film transistor 10, a drive thin film transistor 20, a capacitor 30, and an organic light-emitting diode (OLED) 310. Furthermore, gate lines 251 extending in a direction, data lines 271 crossing the gate lines 251 in an insulating manner, and a common power line 272 are disposed in the drive circuit unit 230.

In the above-described structure of the organic light-emitting display device, the switching thin film transistor 10 is driven in response to gate voltage applied to the gate line 251, and functions to transfer data voltage, applied to the data line 271, to the drive thin film transistor 20. In this case, voltage corresponding to the difference between data voltage transferred from the switching thin film transistor 10 and common voltage applied to the drive thin film transistor 20 from the common power line 272 is stored in the capacitor 30, current corresponding to the voltage stored in the capacitor 30 flows into the organic light-emitting diode 310 via the drive thin film transistor 20, and thus the organic light-emitting diode 310 emits light.

The organic light-emitting diode 310 displays an image by emitting light in response to a drive signal received from the drive circuit unit 230. As shown in FIG. 10, the organic light-emitting diode 310 includes a first electrode 311, an organic light-emitting layer 312, and a second electrode 313 which are sequentially stacked on the substrate 211.

For example, the organic light-emitting layer 312 is a layer in which a hole and an electron injected from the first electrode 311 and the second electrode 313 are combined into an exciton. Depending on the material of the light-emitting layer, the color of light emitted by the organic light-emitting diode may change.

A hole and an electron are injected from the first electrode 311 and the second electrode 313 into the organic light-emitting layer 312, the injected hole and electron are combined into an exciton, and light is emitted when the exciton transitions (e.g., relaxes) from an excited state from a ground state.

The first electrode 311 may be a transmissive electrode having optical transparency, or a reflective electrode having optical reflexibility (or optical reflectance). Furthermore, the second electrode 313 may be formed as a transflective film or reflective film. For example, the first electrode 311 may be a reflective electrode, and the second electrode 313 may be a transflective electrode. Accordingly, light emitted by the organic light-emitting layer 312 is emitted through the second electrode 313. In this case, the organic light-emitting display device 102 according to the third exemplary embodiment of the present disclosure has a top emission-type (or emission-kind) of structure.

One or more metals selected from magnesium (Mg), silver (Ag), gold (Au), calcium (Ca), lithium (Li), chrome (Cr), aluminum (Al), and copper (Cu) or an alloy thereof may be used for the formation of the reflective electrode and the transflective electrode. In this case, the reflective electrode and the transflective electrode may be determined depending on their thickness. Generally, the transflective electrode has a thickness of about 200 nm or less. As the thickness of the transflective electrode decreases, the transmittance of light increases. In contrast, as the thickness of the transflective electrode increases, the transmittance of light decreases.

For example, the first electrode 311 may include a reflective film including one or more metals selected from magnesium (Mg), silver (Ag), gold (Au), calcium (Ca), lithium (Li), chrome (Cr), aluminum (Al), and copper (Cu), and a transparent conductive film disposed on the reflective film. The transparent conductive film has a high work function, and thus the first electrode 311 can desirably inject holes into the organic light-emitting layer 312.

Furthermore, the first electrode 311 may have a three-layer film structure in which a transparent conductive film, a reflective film, and a transparent conductive film are sequentially stacked on top of one another.

The second electrode 313 may be formed as a transflective film including one or more metals selected from magnesium (Mg), silver (Ag), gold (Au), calcium (Ca), lithium (Li), chrome (Cr), aluminum (Al), and copper (Cu).

A pixel defining layer 280 has an opening. The opening of the pixel defining layer 280 exposes part of the first electrode 311. The organic light-emitting layer 312 and the second electrode 313 are sequentially stacked on the first electrode 311 in the opening of the pixel defining layer 280. In this case, the second electrode 313 is formed not only on the organic light-emitting layer 312 but also on the pixel defining layer 290. Meanwhile, a hole injection layer, a hole transport layer, an electron transport layer, and an electron injection layer are also disposed between the pixel defining layer 280 and the second electrode 313. The organic light-emitting diode 310 generates light in the organic light-emitting layer 312 located within the opening of the pixel defining layer 290. Accordingly, the pixel defining layer 280 may define a light emission region.

A thin film encapsulation layer 320 may be further disposed on the second electrode. The thin film encapsulation layer 320 is a layer configured to protect the organic light-emitting diode 310. The thin film encapsulation layer 320 includes one or more selected from inorganic films 321 and 323 and one or more organic films 322, and prevents external air, such as moisture or oxygen, from infiltrating into the organic light-emitting diode 310 (or reduces a likelihood or amount of such infiltration).

The thin film encapsulation layer 320 has a structure in which the inorganic films 321 and 323 and the organic film 322 are alternately stacked. Although the thin film encapsulation layer 320 includes two inorganic films 321 and 323 and one organic film 322 in FIG. 10, the second exemplary embodiment of the present disclosure is not limited thereto.

The inorganic films 321 and 323 include one or more inorganic materials selected from Al₂O₃, TiO₂, ZrO, SiO₂, AlON, AlN, SiON, Si₃N₄, ZnO, and Ta₂O₅. These inorganic films 321 and 323 may be formed using various suitable methods available to those skilled in the art.

The organic film 322 includes a polymer material. In this case, the polymer material includes acrylic resin, epoxy resin, polyimide, polyethylene, etc. Furthermore, the organic film 322 is formed via thermal deposition. However, the second exemplary embodiment of the present disclosure is not limited to thermal deposition, but the organic film 322 may be formed using various suitable methods available to those skilled in the art.

The inorganic films 321 and 323 in which the densities of thin films are high, chiefly suppress or reduce the infiltration of moisture or oxygen. The infiltration of moisture and oxygen into the organic light-emitting diode 310 is blocked chiefly by the inorganic films 321 and 323. Meanwhile, moisture and oxygen having passed through the inorganic films 321 and 323 are blocked by the organic film 322. However, the organic film 322 has a lower moisture prevention (or reduction) effect than the inorganic films 321 and 323. However, the organic film 322 not only suppresses or reduces the infiltration of moisture, but also performs the function of a buffer layer configured to reduce stress between layers between the inorganic films 321 and 323. Furthermore, the organic film 322 has a flattening characteristic, and thus the highest surface of the thin film encapsulation layer 320 is flattened.

The thin film encapsulation layer 320 may have a thin thickness of about 10 μm or less. Accordingly, the organic light-emitting display device 101 may also have a thin thickness. Through the application of the thin film encapsulation layer 320, the organic light-emitting display device 101 can have a flexible characteristic.

In the organic light-emitting display device 101 according to the second exemplary embodiment of the present disclosure, the polarizing unit 100 according to the first exemplary embodiment of the present disclosure is disposed on the above-described display panel 200. In this case, the polarizing unit 100 may have a small thickness, excellent optical reliability, and excellent flexibility compared to prior art. Accordingly, the organic light-emitting display device 101 according to the present disclosure can be made thin, and external light can be effectively prevented via the polarizing unit 100 (or the likelihood of amount external light entering the organic light-emitting display device can be reduced), thereby improving visibility.

Since a description of the polarizing film 100 is the same as described in connection with the first exemplary embodiment, redundant description thereof is not repeated here.

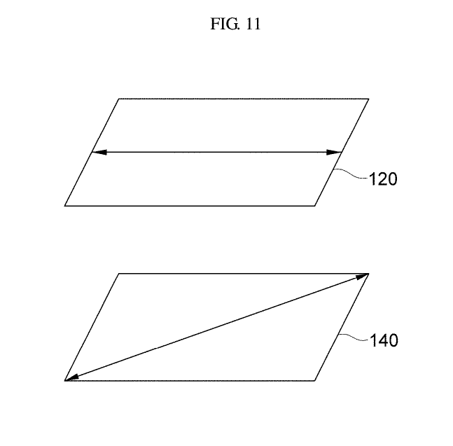

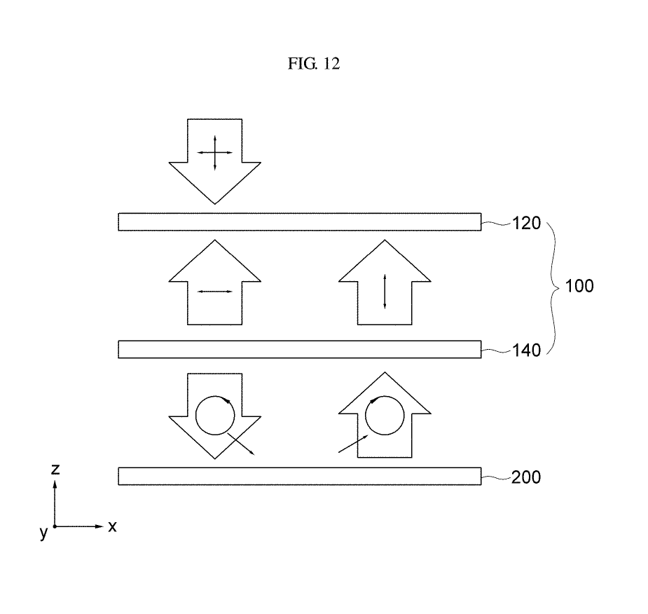

Referring to FIGS. 11-12 together, there will be schematically described the reflection prevention (or reduction) principle of the polarizing unit 100 according to the first exemplary embodiment of the present disclosure.

Referring to FIG. 11, the arrows marked on the coating retarder 140 and the coating polarizer 120 represent respective optical axis directions. As shown in this drawing, the optical axis directions of the coating retarder 120 and the coating polarizer 140, respectively, form an angle of 45 degrees.

In the polarizing unit 100 configured as described above, light incident from a location below the coating retarder 140 is subjected to a phase delay of λ/4 via the coating retarder 140, is converted into linearly polarized light via the coating polarizer 120, and passes through the polarizing unit 100.

In contrast, as shown in FIG. 12, light incident from a location above the polarizing unit 100 is converted into linearly polarized light having only a component polarized in a set or predetermined direction while passing through the coating polarizer 120. In this case, the polarization direction of the linearly polarized light is parallel (e.g., substantially parallel) to the polarization direction of the coating polarizer 120. The linearly polarized light is converted into circularly polarized light while passing through the coating retarder 140. Thereafter, the circularly polarized light is reflected from the display panel 200 including a substrate, electrodes, etc. disposed under the polarizing unit 100. In this case, the polarization direction of the circularly polarized light is reversed. For example, left circularly polarized light is converted into right circularly polarized light, or right circularly polarized light is converted into left circularly polarized light. The circularly polarized light the polarization direction of which has been changed is converted into linearly polarized light while passing through the coating retarder 140. In this process, the polarization direction of the linearly polarized light is perpendicular (e.g., substantially perpendicular) to the polarization direction which is formed while light is passing through the coating polarizer 120 in its early stage. Accordingly, the linearly polarized light converted while passing through the coating retarder 140 does not (or substantially does not) pass through the coating polarizer 120, but is absorbed into the coating polarizer 120.

As a result, light incident on polarizing unit 100 from the outside does not exit (or substantially does not exit) through the polarizing unit 100 to the outside, whereas light incident on polarizing unit 200 from the display panel 200 under the polarizing unit 100 can pass through the polarizing unit 100. Accordingly, a viewer can view a clear image from which an external light component has been removed.

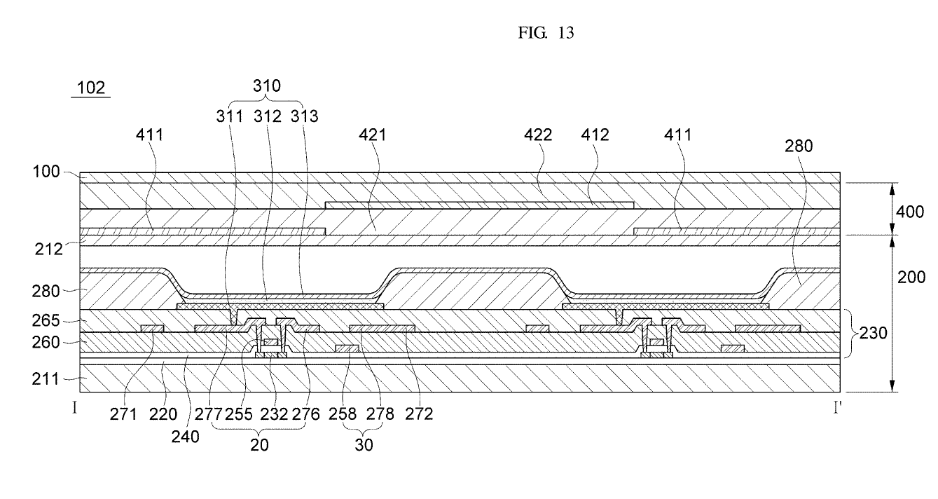

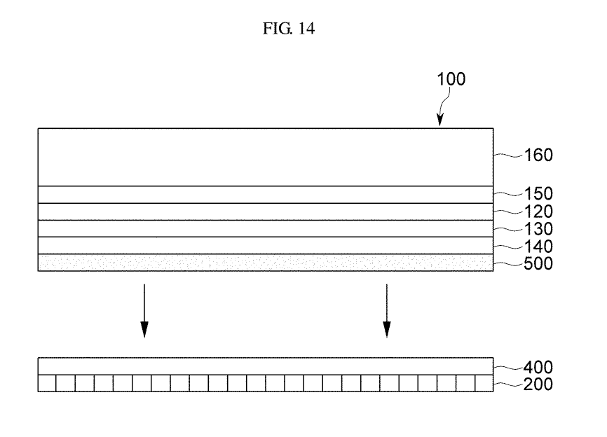

The disclosure organic light-emitting display device according to the third exemplary embodiment of the present will be described. FIGS. 13-14 are sectional views of the organic light-emitting display device 102 according to the third exemplary embodiment of the present disclosure.

The organic light-emitting display device 102 according to the third exemplary embodiment of the present disclosure includes a display panel 200, a polarizing unit 100 disposed on the display panel 200, and a touch sensing unit 400 disposed between the display panel 200 and the polarizing unit 100.

Since the configurations of the display panel 200 and the polarizing unit 100 are the same (e.g., substantially the same) as those described in connection with the second exemplary embodiment, redundant descriptions thereof are not repeated here.

Although a description is given on the assumption that the touch sensing unit 400 is an on-cell touch sensing unit disposed directly on the display panel 200 without a separate substrate, the touch sensing unit 400 is not limited thereto. The touch sensing unit 400 may be formed on a separate substrate and then disposed on the display panel 200, or may be formed in an in-cell manner in which the touch sensing unit 400 is formed inside the display panel 200.

Furthermore, although a description is given on the assumption that the touch sensing unit 400 according to the third exemplary embodiment of the present disclosure has a structure in which a drive electrode and a sensing electrode configured to detect capacitance are disposed in different layers, the touch sensing unit 400 is not limited thereto. The touch sensing unit 400 may have a structure in which sensing electrodes configured to detect capacitance are disposed in the same layer and divided by a bridge electrode.

As shown in FIG. 13, the touch sensing unit 400 includes a plurality of drive electrodes 411 disposed on the display panel 200, a first insulating layer 421 disposed on the plurality of drive electrodes 411, a plurality of sensing electrodes 412 disposed on the first insulating layer 421, and a second insulating layer 422 disposed on the sensing electrode 412. However, the touch sensing unit 400 may include only a plurality of sensing electrodes 412 and a second insulating layer 422.

The shapes of the drive electrode 411 and sensing electrode 412 are not particularly limited. They may be, for example, diamond, triangular, rectangular, or mesh shapes.

The drive electrode 411 and the sensing electrode 412 may have a size suitable or appropriate for the detection of touches based on the size and purpose of the display device. For example, the area of the drive electrode 411 and the sensing electrode 412 may be in a range of about a few square millimeters (mm²) to a few tens of square millimeters (mm²).

The drive electrode 411 and the sensing electrode 412 may include a metal or transparent conductive oxide (TCO). The transparent conductive oxide (TCO) may include at least one selected from the group consisting of an indium tin oxide (ITO), an indium zinc oxide (IZO), a zinc oxide (ZnO), a carbon nanotube (CNT), and graphene.

In the organic light-emitting display device 102 according to the third exemplary embodiment of the present disclosure, the polarizing unit 100 is disposed on the above-described touch sensing unit 400. Since a description of the polarizing unit 100 is the same (e.g., substantially the same) as described in connection with the first exemplary embodiment, redundant description thereof is not repeated here.

As shown in FIG. 14, the polarizing unit 100 may be disposed on the second insulating layer 422 via an adhesive layer 500. The adhesive layer 500 may include a transparent adhesive material. For example, the adhesive layer may be optical clear resin (OCR).

The polarizing unit according to the present disclosure may have a small thickness, flexibility, and excellent optical reliability. The display device according to the present disclosure, to which the polarizing unit has been applied, may enable a lightweight and thin device, may exhibit excellent image visibility, and may have low damage possibility even when it is repetitively or continuously bent or folded for a long period of time.

Furthermore, according to the method of manufacturing a polarizing unit according to the present disclosure, the polarizing unit is not manufactured by stacking and attaching films in a plurality of layers, and thus the method of manufacturing a polarizing unit can reduce manufacturing cost and can curtail or reduce processing time, thereby improving manufacturing efficiency.

The features of the present disclosure are not limited to the above-described features, but further various features are included in the present disclosure.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, acts, operations, elements, and/or components, but do not preclude the presence or addition of one or more other features, integers, acts, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the terms “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

While the embodiments of the present disclosure have been described with reference to the accompanying drawings, it will be appreciated by those having ordinary knowledge in the art to which the present disclosure pertains that the present disclosure may be practiced in other forms without changing the technical spirit of the present disclosure. Therefore, the above-described embodiments should be understood as be illustrative, not limitative, in all aspects.

What is claimed is:

1. A polarizing unit comprising:
an upper substrate;
a coating polarizer disposed on one surface of the upper substrate;
a coating retarder disposed on one surface of the coating polarizer; and
pressure-sensitive adhesive layers respectively disposed between the upper substrate and the coating polarizer and between the coating polarizer and the coating retarder,
wherein the upper substrate comprises a flexible material having elasticity.

2. The polarizing unit of claim 1, wherein the flexible material having elasticity of the upper substrate comprises a material having an elastic modulus of about 1 GPa or less.

3. The polarizing unit of claim 1, wherein the upper substrate comprises one or more selected from an olefin elastomer, a urethane elastomer, and a polyester elastomer.

4. The polarizing unit of claim 1, wherein the upper substrate comprises one or more selected from polyethyleneterephtalate (PET), polyethylenenaphthalate (PEN), polydimethylsiloxane (PDMS), polyimide (PI), polyimideamide, polyetherimide (PEI), polyacrylate (PAC), and polymethylmethacrylate (PMMA).

5. The polarizing unit of claim 1, wherein:
the coating retarder delays a phase of transmitted light by about λ/4; and
optical axis directions of the coating retarder and the coating polarizer, respectively, form an angle of about 45 degrees.

6. The polarizing unit of claim 1, wherein the coating polarizer and the coating retarder each comprise a liquid crystal compound.

7. The polarizing unit of claim 1, wherein the pressure-sensitive adhesive layer comprises one or more selected from a natural rubber adhesive, a styrene/butadiene latex adhesive, ABA block copolymer thermoplastic rubber (wherein A is a thermoplastic polystyrene end block and B is an intermediate block of polyisoprene rubber, polybutadiene rubber, polyethylene rubber, or polybutylene rubber), butyl rubber, polyisobutylene, an acrylic polymer adhesive, and a vinyl ether polymer adhesive.

8. A method of manufacturing a polarizing unit, the method comprising:
forming a coating polarizer on one surface of a base substrate;
forming a pressure-sensitive adhesive layer on one surface of the coating polarizer;
forming a coating retarder on one surface of a transfer substrate;
attaching the coating retarder onto the pressure-sensitive adhesive layer, and removing the transfer substrate;
removing the base substrate from the coating polarizer; and
forming a pressure-sensitive adhesive layer on a back of the coating polarizer free from the base substrate, and attaching an upper substrate onto the latter pressure-sensitive adhesive layer.

9. The method of claim 8, wherein forming the coating polarizer on the one surface of the base substrate comprises:
forming an alignment layer on a top surface of the base substrate; and
forming a liquid crystal coating layer on the alignment layer by applying a coating layer formation composition, comprising a liquid crystal compound and a dichroic dye, onto the alignment layer.

10. The method of claim 8, wherein forming the coating retarder on the one surface of the transfer substrate comprises:
forming an alignment layer on the transfer substrate; and
forming a liquid crystal coating layer on the alignment layer by applying a coating layer formation composition, comprising a liquid crystal compound, onto the alignment layer.

11. A display device comprising:
a display panel capable of displaying images; and
a polarizing unit disposed on a top of the display panel;
wherein the polarizing unit comprises:
an upper substrate;
a coating polarizer disposed on one surface of the upper substrate;
a coating retarder disposed on one surface of the coating polarizer; and
pressure-sensitive adhesive layers respectively disposed between the upper substrate and the coating polarizer and between the coating polarizer and the coating retarder; and
wherein the upper substrate comprises a flexible material having elasticity.

12. The display device of claim 11, wherein the flexible material having elasticity of the upper substrate comprises a material having an elastic modulus of about 1 GPa or less.

13. The display device of claim 11, wherein the upper substrate comprises one or more selected from an olefin elastomer, a urethane elastomer, and a polyester elastomer.

14. The display device of claim 11, wherein the upper substrate comprises one or more selected from polyethyleneterephtalate (PET), polyethylenenaphthalate (PEN), polydimethylsiloxane (PDMS), polyimide (PI), polyimideamide, polyetherimide (PEI), polyacrylate (PAC), and polymethylmethacrylate (PMMA).

15. The display device of claim 11, wherein:
the coating retarder delays a phase of transmitted light by about λ/4; and
optical axis directions of the coating retarder and the coating polarizer, respectively, form an angle of about 45 degrees.

16. The display device of claim 11, further comprising a touch sensing unit disposed on the display panel.

17. The display device of claim 16, further comprising an adhesive layer disposed between the polarizing unit and the touch sensing unit.

18. The display device of claim 11, wherein the display panel comprises:
a substrate;
a drive circuit unit disposed on the substrate;
light emitting diodes coupled to the drive circuit unit; and
a sealing layer covering the light emitting diodes.

19. The display device of claim 11, wherein the upper substrate is a window.

20. The display device of claim 11, wherein the display panel is a stretchable display panel.
